(19) United States
(12) Patent Application Publication
(10) Pub. No.: US 2026/0282394 A1
(43) Pub. Date: Sep. 17, 2026

(54) HIGH BANDWIDTH MEMORY SYSTEM, METHOD AND DEVICE

(71) Applicant: Marvell Asia Pte Ltd, Singapore (SG)

(72) Inventors: Ting Zheng, San Jose, CA (US); Sidney William Allman, Stittsville (CA); Carlos Macian Ruiz, Los Gatos, CA (US); Zachary Baldwin, Burlington, VT (US); Kazin Simon Blacklow, Burlington, VT (US); Aatreya Chakravarti, Winooski, VT (US); John Edward Gregory, JR., Dummerston, VT (US); Samer Akiki, Redwood City, CA (US); Wolfgang Sauter, Starksboro, VT (US); Joshua F. Dillon, Stowe, VT (US); Mark William Kuemerle, Essex Junction, VT (US)

(21) Appl. No.: 19/565,366

(22) Filed: Mar. 12, 2026

Related U.S. Application Data
(60) Provisional application No. 63/772,382, filed on Mar. 14, 2025.

(51) Int. Cl. H10B 80/00; H10D 80/30; H10W 40/20; H10W 70/60; H10W 90/15; H10W 90/20

(52) U.S. Cl. CPC H10B 80/00; H10D 80/30; H10W 40/231; H10W 70/614; H10W 90/15; H10W 90/297

(57) ABSTRACT

A high bandwidth memory system including a substrate, an interposer, a dynamic random access memory (DRAM) stack, an application specific integrated circuit (ASIC) and a processing unit. The ASIC is able to be positioned on top of the DRAM stack such that it does not need a field of through silicon vias or is able to comprise a plurality of TSV sub-fields that enable routing between the TSV subfields.

### RELATED APPLICATIONS

This application claims priority under 35 U.S.C. § 119(e) of the co-pending U.S. provisional patent application Ser. No. 63/772,382 filed Mar. 14, 2025, and titled “ASIC-on-Top in Custom High Bandwidth Memory (HBM),” which is hereby incorporated by reference.

### FIELD OF INVENTION

The present invention relates to high bandwidth memory systems, methods and devices. More particularly, the present invention relates to custom high bandwidth memory systems, methods and devices.

### BACKGROUND OF THE INVENTION

High bandwidth memory (HBM), which includes standard HBM and custom HBM variants, is a critical component in current artificial intelligence/machine learning (AI/ML) systems due to its high bandwidth. In a typical custom HBM, a custom application specific integrated circuit (ASIC) is positioned underneath a dynamic random access memory (DRAM) stack as a base die, capable of integrating multiple functions. However, the custom HBM suffers from several challenges. Firstly, the on-chip signals within the custom ASIC encounter routing challenges due to the needed extensive 3D PHY area on the chip and the associated through silicon via (TSV) field. Secondly, the custom ASIC face a long thermal path to dissipate heat at the top side where the cooling solution is positioned. Finally, there is a significant thermal coupling between the main die and custom HBM, particularly when they are adjacent in advanced packaging.

### RIEF SUMMARY OF THE INVENTION

A high bandwidth memory system, method and device including a substrate, an interposer, a dynamic random access memory (DRAM) stack, an application specific integrated circuit (ASIC) and a processing unit (e.g. XPU, GPU, CPU). The ASIC is able to be positioned on top of the DRAM stack such that it does not need a field of through silicon vias or is able to comprise a plurality of TSV sub-fields that enable routing between the TSV subfields.

A first aspect is directed to a high bandwidth memory system. The system comprises a substrate, an interposer coupled with the substrate, a dynamic random access memory (DRAM) stack having a top and a bottom, wherein the bottom of the DRAM stack is electrically coupled with the interposer, an application specific integrated circuit (ASIC) electrically coupled to the top of the DRAM stack and a processing unit positioned adjacent to the DRAM stack and electrically coupled with the interposer. In some embodiments, the ASIC does not include through silicon vias (TSVs) electrically coupled with the DRAM stack. In some embodiments, the ASIC comprises one or more thermal vias that facilitate cooling of the ASIC. In some embodiments, the ASIC is positioned face down such that a top surface of the ASIC is coupled with the top of the DRAM stack. In some embodiments, the ASIC comprises control logic and custom logic physically separated by a three-dimensional physical layer (3D PHY), and further wherein the control logic is communicatively coupled with the custom logic via routing components that extend through the 3D PHY. In some embodiments, the ASIC further comprises a built-in self-test component, a central processing unit, and a die-to-die communication interface. In some embodiments, the custom logic comprises a double data rate physical layer (DDR PHY).

Another aspect is directed to a high bandwidth memory circuit. The circuit comprises a dynamic random access memory (DRAM) stack having a top and a bottom and an application specific integrated circuit (ASIC) electrically coupled to the top of the DRAM stack, wherein the ASIC does not include through silicon vias (TSVs) electrically coupled with the DRAM stack. In some embodiments, the ASIC comprises one or more thermal vias that facilitate cooling of the ASIC. In some embodiments, the ASIC is positioned face down such that a top surface of the ASIC is coupled with the top of the DRAM stack. In some embodiments, the ASIC comprises control logic and custom logic physically separated by a three-dimensional physical layer (3D PHY), and further wherein the control logic is communicatively coupled with the custom logic via routing components that extend through the 3D PHY. In some embodiments, the ASIC further comprises a built-in self-test component, a central processing unit, and a die-to-die communication interface. In some embodiments, the custom logic comprises a double data rate physical layer (DDR PHY).

Another aspect is directed to a method of implementing a high bandwidth memory system. The method comprises providing a substrate, coupling an interposer onto the substrate, electrically coupling a bottom of a dynamic random access memory (DRAM) stack onto the interposer, electrically coupling an application specific integrated circuit (ASIC) to a top of the DRAM stack and electrically coupling a processing unit with the interposer such that the processing unit is positioned adjacent to the DRAM stack. In some embodiments, the ASIC does not include through silicon vias (TSVs) electrically coupled with the DRAM stack. In some embodiments, the ASIC comprises one or more thermal vias that facilitate cooling of the ASIC. In some embodiments, electrically coupling the ASIC to the top of the DRAM stack comprises positioning the ASIC face down such that a top surface of the ASIC is coupled with the top of the DRAM stack. In some embodiments, the ASIC comprises control logic and custom logic physically separated by a three-dimensional physical layer (3D PHY), and further wherein the control logic is communicatively coupled with the custom logic via routing components that extend through the 3D PHY. In some embodiments, the ASIC further comprises a built-in self-test component, a central processing unit, and a die-to-die communication interface. In some embodiments, the custom logic comprises a double data rate physical layer (DDR PHY).

Another aspect is directed to a high bandwidth memory system. The system comprises means for supporting,. means for interposing coupled with the means for supporting, means for providing a dynamic random access memory (DRAM) having a top and a bottom, wherein the bottom of the means for providing DRAM is electrically coupled with the means for interposing, application specific means for computing electrically coupled to the top of the means for providing DRAM and means for processing positioned adjacent to the means for providing DRAM and electrically coupled with the means for interposing.

Another aspect is directed to a high bandwidth memory system. The system comprises a substrate, an application specific integrated circuit (ASIC) having a top and a bottom and including custom logic and control logic physically separated by a three-dimensional physical layer (3D PHY), wherein the 3D PHY includes a plurality of through silicon via (TSV) subfields separated by one or more gaps, and further wherein the custom logic is communicatively coupled with the control logic via routing components that extend through the gaps between the TSV subfields of the 3D PHY, an interposer electrically coupled with the substrate and the bottom of the ASIC, a dynamic random access memory (DRAM) stack electrically coupled with the top of the ASIC and a processing unit positioned adjacent to the ASIC and the DRAM stack and electrically coupled with the interposer. In some embodiments, the ASIC further comprises a built-in self-test component, a central processing unit, and a die-to-die communication interface. In some embodiments, the custom logic comprises a double data rate physical layer (DDR PHY).

### BRIEF DESCRIPTION OF THE DRAWINGS

FIG. 1 illustrates a cross-sectional view (at line A of FIG. 2) of a high bandwidth memory system according to some embodiments.

FIG. 2 illustrates a top view of the ASIC according to some embodiments.

FIG. 3 illustrates a cross-sectional view (at line B of FIG. 4) of a high bandwidth memory system according to some embodiments.

FIG. 4 illustrates a top view of the ASIC of the system according to some embodiments.

FIG. 5 illustrates a cross-sectional view (at line C of FIG. 6) of a high bandwidth memory system according to some embodiments.

FIG. 6 illustrates a top view of the ASIC of the system according to some embodiments.

FIG. 7 illustrates a method of implementing a high bandwidth memory system 100 according to some embodiments.

### DETAILED DESCRIPTION OF THE INVENTION

In the following description, numerous details are set forth for purposes of explanation. However, one of ordinary skill in the art will realize that the invention can be practiced without the use of these specific details. Thus, the present invention is not intended to be limited to the embodiments shown but is to be accorded with the widest scope consistent with the principles and features described herein.

Embodiments are directed to a high bandwidth memory system, method and device including a substrate, an interposer, a dynamic random access memory (DRAM) stack, an application specific integrated circuit (ASIC) and a processing unit. The ASIC is able to be positioned on top of the DRAM stack such that it does not need a field of through silicon vias or is able to comprise a plurality of TSV sub-fields that enable routing between the TSV subfields. As a result, the high bandwidth memory system, method and device has the benefit of providing less thermal resistance/shorter thermal path from the custom ASIC to the cooling solution to dissipate heat via the cooling solution. Further, the system, method and device provides less thermal coupling between the custom HBM and main processing unit (or units) in the package reducing unwanted heat exchange/buildup between the two. Also, the system, method and device provides the advantage of enabling the addition of one or more thermal through silicon vias that provide increased and efficient heat dissipation. Finally, the system, method and device provides the advantage of avoiding on-die signal routing congestion via either a lack of a through silicon via field, or the use of discontinuous subfields that provide routing pathways therethrough.

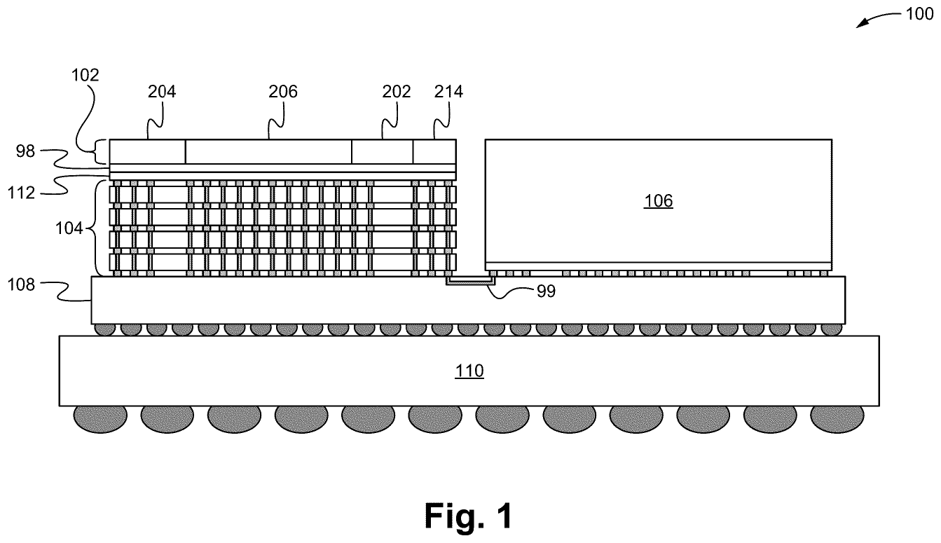

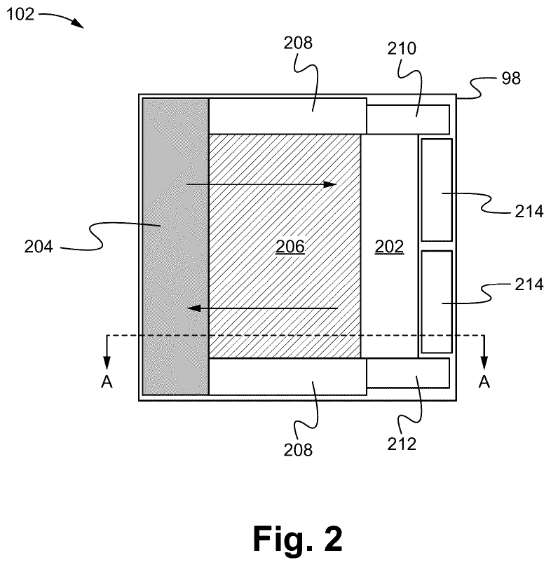

FIG. 1 illustrates a cross-sectional view (at line A of FIG. 2) of a high bandwidth memory system 100 according to some embodiments. As shown in FIG. 1, the system 100 comprises a substrate 110, an interposer 108, a dynamic random access memory (DRAM) stack 104, an application specific integrated circuit (ASIC) 102 and a processing unit (XPU) 106. The interposer 108 is physically and/or electrically coupled to the top of the substrate 110, with the DRAM stack 104 and the XPU 106 physically and/or electrically coupled with a top side of the interposer 108. In particular, because the ASIC 102 is positioned on top of the DRAM stack 104 instead of between the stack 104 and the interposer 108, there is less thermal coupling between the ASIC/DRAM stack and XPU 106 in the package reducing unwanted heat exchange/buildup between the two. Further, by being uncovered, heat from the ASIC 102 is able to more readily dissipate to the surrounding air.

In some embodiments, each of the substrate 110, the interposer 108, the DRAM stack 104 and the XPU 106 are able to be coupled together via a plurality of conductive bumps (e.g. micro-bumps (C2), C4 bumps, or other types of solder bumps). Alternatively, other types of electrical connections are able to be used for coupling one or more of the substrate 110, the interposer 108, the DRAM stack 104 or the XPU 106 as described above. Additionally, the interposer 108 is able to electrically couple together the DRAM stack 104 and the XPU 106 via one or more conductive layers 99. The ASIC 102 is electrically and/or physically coupled to a top of the DRAM stack 104 via a bonding element 112 (e.g. microbump or hybrid bond). The ASIC 102 is able to be coupled to the DRAM stack 104 face-up or face-down as desired.

The substrate 110 is able to comprise a laminate material (e.g. printed circuit board/fiberglass-reinforced epoxy). The interposer 108 is able to have a plurality of conductive layers 99 and be formed of silicon, glass, organic laminates, ceramics, other material or a combination thereof. The XPU 106 is able to comprise any type of processing unit including, but not limited to, a central processing unit (CPU), a graphics processing unit (GPU), a specialized and/or customized, accelerator processing unit, an artificial intelligence chip/accelerator, a data processing unit (DPU), an infrastructure processing unit (IPU), an application specific integrated circuit (ASIC) and/or other types of processing units. The XPU 106 is configured to communicate with the ASIC 102 and/or DRAM stack 104 during operation. The DRAM stack 104 is able to comprise a plurality of DRAM die stacked on top of each other and electrically coupled together (e.g. via micro bumps, hybrid bond and/or through silicon vias (TSV)).

FIG. 2 illustrates a top view of the ASIC 102 according to some embodiments. As shown in FIG. 2, the ASIC 102 comprises control logic 202, custom logic 204, a three-dimensional physical layer (3D PHY) 206, electrical signal routing 208, one or more central processing units 210, a built-in self-test (BIST) circuit 212, and one or more die-to-die (D2D) units 214. Alternatively, one or more of the custom logic 204, the three-dimensional physical layer (3D PHY) 206, the electrical signal routing 208, the one or more central processing units 210 and/or the built-in self-test (BIST) circuit 212 are able to be omitted. Also, each of the components of the ASIC 102 are able to be formed on/coupled with an ASIC substrate 98 (e.g. silicon substrate).

The D2D units 214 are able to facilitate communication between the ASIC 102 and the DRAM stack 104 and/or the XPU 106. In some embodiments, the control logic 202 is able to achieve core memory management including memory bank management, optimizing memory performance and throughput, issuing memory read/write commands, managing initialization, training, refresh, different power-modes and/or has Reliability-Availability-Serviceability (RAS) features. In some embodiments, the control logic 202 is also able to support joint electron device engineering council (JEDEC) HBM data rate and/or is able to be interfaced with a microchip bus. In some embodiments, the custom logic 204 comprises integrated tailored/custom logic, such as controllers or accelerators. For example, the custom logic 204 is able to be configured as computing logic and/or high-speed serializer/deserializer (SerDes). In some embodiments, the custom logic 204 comprises a double data rate physical layer (DDR PHY).

The routing 208 is able to provide conductive pathways that electrically couple the control logic 202 with the custom logic 204. The 3D PHY 206 is able to be positioned between the control logic 202 and the custom logic 204 and therefore include conductive routing that electrically and communicatively couples the control logic 202 and the custom logic 204 together. In particular, because the ASIC 102 is positioned on top of the DRAM stack 104 (instead of on the bottom), the 3D PHY 206 is able to be free of TSVs and instead include room for the conductive routing. Thus, the system 100 provides the advantage of more efficient electrical/communicative routing between the control logic 202 and the custom logic 204. In other words, the system 100 increases footprint efficiency and alleviates on-die signal routing congestion by eliminating the needs for a fenced off field of TSVs.

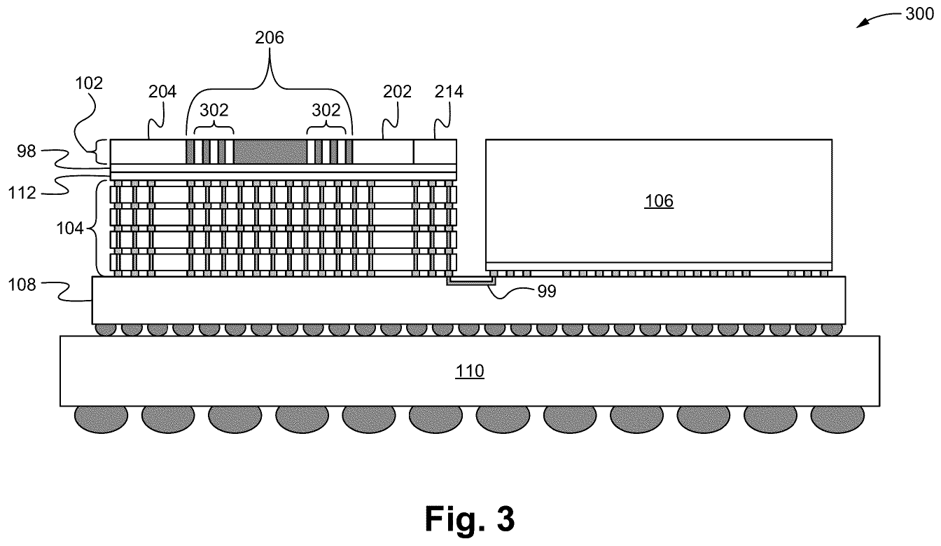

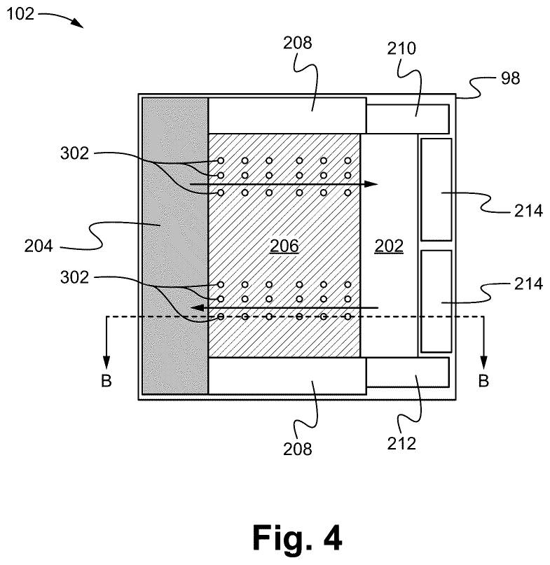

FIG. 3 illustrates a cross-sectional view (at line B of FIG. 4) of a high bandwidth memory system 300 according to some embodiments. FIG. 4 illustrates a top view of the ASIC 102 of the system 300 according to some embodiments. The high bandwidth memory system 300 of FIG. 3 and the ASIC 102 of FIG. 4 are able to be substantially similar to the system 100 of FIG. 1 and the ASIC 102 of FIG. 2 except for the differences described herein. In particular, as shown in FIGS. 3 and 4, the 3D PHY 206 of the ASIC 102 comprises one or more thermal vias 302 in order to facilitate more efficient cooling of the system 100. For example, the thermal vias 302 are able to be coupled with a cooling solution (not shown) in order to provide an efficient heat dissipation for the system 100.

In some embodiments, the thermal vias 302 comprise specialized copper-filled holes. Alternatively, the thermal vias 302 are able to be formed of other materials. In any case, the thermal vias 302 are able to act as tiny heat pipes, creating low-resistance pathways to draw heat away from hot components (like the ASIC 102) and spread it across internal copper planes or to external heat sinks, preventing hotspots and improving device reliability and lifespan by offering crucial thermal management. Although as shown in FIGS. 3 and 4, the 3D PHY 206 comprises 36 thermal vias 302, more or less vias 302 are able to be used. Further, although as shown in FIGS. 3 and 4, the thermal vias 302 are organized into six rows of six vias 302 (with three rows adjacent to the custom logic 204 and three rows adjacent to the control logic 202), the thermal vias 302 are able to be positioned in any formation or non-formation through the 3D PHY 206. Finally, although as shown in FIGS. 3 and 4, each of the thermal vias 302 are of the same size and shape (e.g. cylindrical) one or more of the thermal vias 302 are able to have different sizes (e.g. diameters, depths, angles) and/or shapes (square, rectangle, oval). In some embodiments, one or more of the thermal vias 302 are through-hole thermal vias (e.g. that go all the way through the ASIC 102). Alternatively, one or more of the thermal vias 302 are able to be blind thermal vias, buried thermal vias and/or other types of thermal vias.

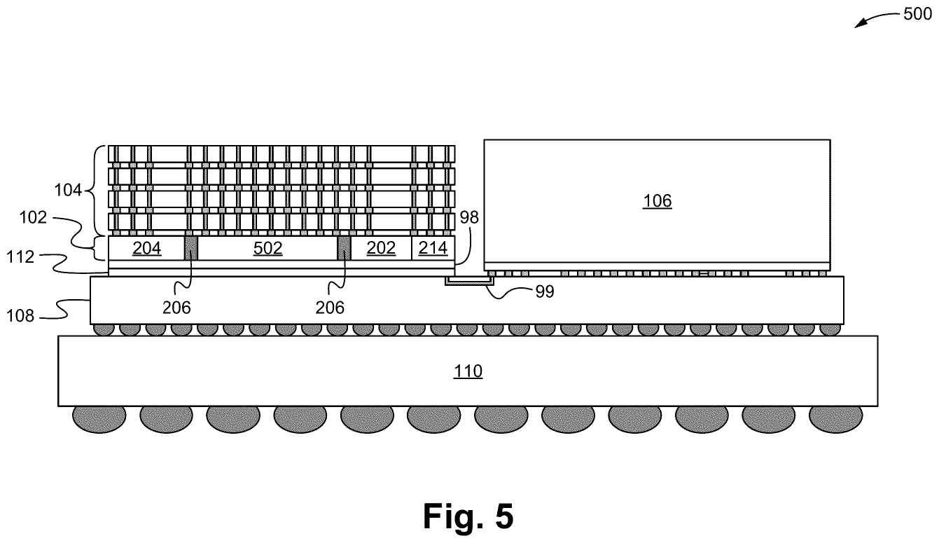

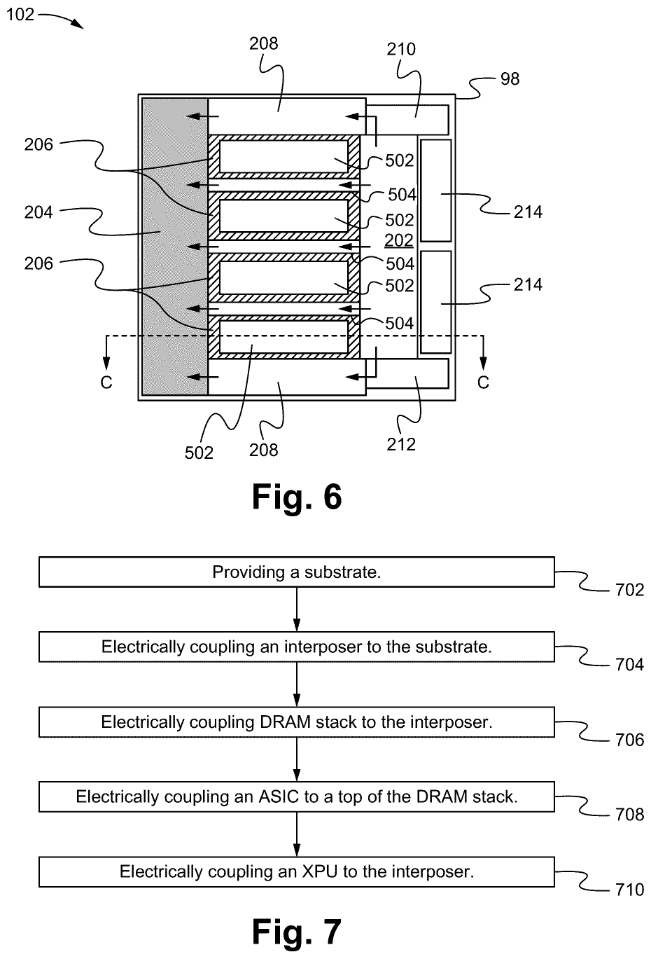

FIG. 5 illustrates a cross-sectional view (at line C of FIG. 6) of a high bandwidth memory system 500 according to some embodiments. FIG. 6 illustrates a top view of the ASIC 102 of the system 500 according to some embodiments. The high bandwidth memory system 500 of FIG. 5 and the ASIC 102 of FIG. 6 are able to be substantially similar to the system 100 of FIG. 1 and the ASIC 102 of FIG. 2 except for the differences described herein. In particular, as shown in FIGS. 5 and 6, the ASIC 102 is positioned one the bottom of the DRAM stack 104 electrically and physically coupled to the bottom of the DRAM stack 104 and the top of the interposer 108. Further as shown in FIG. 6, the 3D PHY 206 of the ASIC 102 comprises one or more through silicon via (TSV) subfields 502 with gaps in between them such that additional routing 504 is able to pass through the 3D PHY 206 (through the gaps) thereby communicative and/or electrically coupling the control logic 202 and the custom logic 204. In particular, because the TSVs are divided into subfields 502 (rather than a large single block/field), the routing 504 is not forced to be positioned around the 3D PHY 206, but rather is able to take the more direct path through the 3D PHY 206.

In some embodiments, the outside routing 208 is able to be omitted in the system 500. Although as shown in FIGS. 5 and 6, the system 500 comprises four TSV subfields 502 and three additional routing paths 504, more or less TSV subfields 502 and/or additional routing paths 504 are able to be used. In some embodiments, an additional routing path 504 is positioned through each gap between the TSV subfields 502. Alternatively, one or more of the gaps between the subfields 502 are able to not have additional routing 504 positioned therethrough. The additional routing 504 is able to be the same as the routing 208 except that it takes a more direct path from the control logic 202 to the custom logic 204. The TSVs are able to communicatively and/or electrically couple the ASIC 102 with the dies (e.g. DRAM dies) of the DRAM stack 104.

FIG. 7 illustrates a method of implementing a high bandwidth memory system 100 according to some embodiments. As shown in FIG. 7, a substrate 110 is provided at the step 702. An interposer 108 is electrically coupled to the substrate 110 at the step 704. A bottom of a DRAM stack 104 is electrically coupled onto the interposer 108 at the step 706. An ASIC 102 is electrically coupled to a top of the DRAM stack 104 at the step 708. An XPU is electrically coupled with the interposer 108 at the step 710. Although according to the numerical order of the steps of FIG. 7, the interposer 108 is coupled, followed by the DRAM stack 104, the ASIC 102 and the XPU, any other order is able to be used. For example, the ASIC 102 is able to be coupled on top of DRAM stack 104 first, then the ASIC 102 and DRAM stack 104 (as coupled together) coupled onto the interposer 108 along with the XPU 106 on interposer 108, then couple the interposer 108 onto the substrate 110.

The XPU 106 is able to be positioned adjacent to the DRAM stack 104 as they are positioned on the interposer 108. In some embodiments, the ASIC 102 does not include through silicon vias (TSVs) electrically coupled with the DRAM stack 104. In some embodiments, the ASIC 102 comprises one or more thermal vias 302 that facilitate cooling of the ASIC 102. In some embodiments, electrically coupling the ASIC 102 to the top of the DRAM stack 104 comprises positioning the ASIC 102 face down such that a top surface of the ASIC 102 is coupled with the top of the DRAM stack 104. Alternatively, electrically coupling the ASIC 102 to the top of the DRAM stack 104 comprises positioning the ASIC 102 face up such that a bottom surface of the ASIC 102 is coupled with the top of the DRAM stack 104. In some embodiments, the ASIC 102 comprises control logic 202 and custom logic 204 physically separated by a three-dimensional physical layer (3D PHY) 206, and further wherein the control logic 202 is communicatively coupled with the custom logic 204 via routing components 208 that extend through the 3D PHY 206. In some embodiments, the ASIC 102 further comprises a built-in self-test component 212, a central processing unit 210, and a die-to-die communication interface 214. In some embodiments, the custom logic 204 comprises a double data rate physical layer (DDR PHY).

The high bandwidth memory system, method and device described herein provides numerous advantages. Specifically, the high bandwidth memory system, method and device has the benefit of providing less thermal resistance/shorter thermal path from the custom ASIC to the cooling solution (and/or ambient air) to dissipate heat via the cooling solution. Further, the system, method and device provides less thermal coupling between the ASIC and XPU in the package reducing unwanted heat exchange/buildup between the two. Also, the system, method and device provides the advantage of enabling the addition of one or more thermal through silicon vias that provide increased and efficient heat dissipation. Finally, the system, method and device provides the advantage of avoiding on-die signal routing congestion via either a lack of a through silicon via field, or the use of discontinuous subfields that provide routing pathways therethrough.

While the system, method and device has been described with reference to numerous specific details, one of ordinary skill in the art will recognize that the invention can be embodied in other specific forms without departing from the spirit of the invention. Thus, one of ordinary skill in the art will understand that the invention is not to be limited by the foregoing illustrative details. For example, although a single component 110 is described as performing multiple functions, it is understood that the functions are able to be divided amongst a plurality of separate components. Further, it should be noted that although not described in detail for the sake of brevity, the system 100 (and/or ASIC/XPU) is able to include (or be a part of) one or more of an integrated circuit, a software defined network, a top of rack switch, artificial intelligence/machine learning device, a network interface, additional memory, additional processors, I/O device(s), buses and/or a storage device. The memory (e.g. of the ASIC/XPU) is able to be any conventional computer memory known in the art such as, but not limited to, a hard drive, DRAM, RAM, SRAM, CDROM, CDRW, DVD, DVDRW, flash memory card or any other storage device. An example of a network interface includes a network card connected to an Ethernet or other type of LAN. The I/O device(s) are able to include one or more of the following: keyboard, mouse, monitor, display, printer, modem, touchscreen, button interface and other devices. In some embodiments, the shared library is able to be a driver for one or more of the I/O devices. Operating system(s), graphical user interface(s), application(s), module(s) and/or other software on the system 100 (and components thereof) are able to be stored in the memory and/or storage devices (e.g. of the ASIC/XPU) and processed as applications are typically processed via the processors and/or additional processors of the system 100. The processes are able to be implemented via hardware, software, firmware and/or a combination of two or more of hardware, software and firmware such as memory, software/firmware and/or processors to execute the software/firmware stored on the memory in order to perform the functions of the processes.

We claim:

1. A high bandwidth memory system, the system comprising:
a substrate;
an interposer coupled with the substrate;
a dynamic random access memory (DRAM) stack having a top and a bottom, wherein the bottom of the DRAM stack is electrically coupled with the interposer;
an application specific integrated circuit (ASIC) electrically coupled to the top of the DRAM stack; and
a processing unit positioned adjacent to the DRAM stack and electrically coupled with the interposer.

2. The system of claim 1, wherein the ASIC does not include through silicon vias (TSVs) electrically coupled with the DRAM stack.

3. The system of claim 1, wherein the ASIC comprises one or more thermal vias that facilitate cooling of the ASIC.

4. The system of claim 1, wherein the ASIC is positioned face down such that a top surface of the ASIC is coupled with the top of the DRAM stack.

5. The system of claim 1, wherein the ASIC comprises control logic and custom logic physically separated by a three-dimensional physical layer (3D PHY), and further wherein the control logic is communicatively coupled with the custom logic via routing components that extend through the 3D PHY.

6. The system of claim 5, wherein the ASIC further comprises a built-in self-test component, a central processing unit, and a die-to-die communication interface.

7. The system of claim 6, wherein the custom logic comprises a double data rate physical layer (DDR PHY).

8. A high bandwidth memory circuit, the circuit comprising:
a dynamic random access memory (DRAM) stack having a top and a bottom; and
an application specific integrated circuit (ASIC) electrically coupled to the top of the DRAM stack, wherein the ASIC does not include through silicon vias (TSVs) electrically coupled with the DRAM stack.

9. The circuit of claim 8, wherein the ASIC comprises one or more thermal vias that facilitate cooling of the ASIC.

10. The circuit of claim 8, wherein the ASIC is positioned face down such that a top surface of the ASIC is coupled with the top of the DRAM stack.

11. The circuit of claim 8, wherein the ASIC comprises control logic and custom logic physically separated by a three-dimensional physical layer (3D PHY), and further wherein the control logic is communicatively coupled with the custom logic via routing components that extend through the 3D PHY.

12. The circuit of claim 11, wherein the ASIC further comprises a built-in self-test component, a central processing unit, and a die-to-die communication interface.

13. The circuit of claim 12, wherein the custom logic comprises a double data rate physical layer (DDR PHY).

14. A method of implementing a high bandwidth memory system, the method comprising:
providing a substrate;
coupling an interposer onto the substrate;
electrically coupling a bottom of a dynamic random access memory (DRAM) stack onto the interposer;
electrically coupling an application specific integrated circuit (ASIC) to a top of the DRAM stack; and
electrically coupling a processing unit with the interposer such that the processing unit is positioned adjacent to the DRAM stack.

15. The method of claim 14, wherein the ASIC does not include through silicon vias (TSVs) electrically coupled with the DRAM stack.

16. The method of claim 14, wherein the ASIC comprises one or more thermal vias that facilitate cooling of the ASIC.

17. The method of claim 14, wherein electrically coupling the ASIC to the top of the DRAM stack comprises positioning the ASIC face down such that a top surface of the ASIC is coupled with the top of the DRAM stack.

18. The method of claim 14, wherein the ASIC comprises control logic and custom logic physically separated by a three-dimensional physical layer (3D PHY), and further wherein the control logic is communicatively coupled with the custom logic via routing components that extend through the 3D PHY.

19. The method of claim 18, wherein the ASIC further comprises a built-in self-test component, a central processing unit, and a die-to-die communication interface.

20. The method of claim 19, wherein the custom logic comprises a double data rate physical layer (DDR PHY).

21. A high bandwidth memory system, the system comprising:
means for supporting;
means for interposing coupled with the means for supporting;
means for providing a dynamic random access memory (DRAM) having a top and a bottom, wherein the bottom of the means for providing DRAM is electrically coupled with the means for interposing;
application specific means for computing electrically coupled to the top of the means for providing DRAM; and
means for processing positioned adjacent to the means for providing DRAM and electrically coupled with the means for interposing.

22. A high bandwidth memory system, the system comprising:
a substrate;
an application specific integrated circuit (ASIC) having a top and a bottom and including custom logic and control logic physically separated by a three-dimensional physical layer (3D PHY), wherein the 3D PHY includes a plurality of through silicon via (TSV) subfields separated by one or more gaps, and further wherein the custom logic is communicatively coupled with the control logic via routing components that extend through the gaps between the TSV subfields of the 3D PHY;
an interposer electrically coupled with the substrate and the bottom of the ASIC;
a dynamic random access memory (DRAM) stack electrically coupled with the top of the ASIC; and
a processing unit positioned adjacent to the ASIC and the DRAM stack and electrically coupled with the interposer.

23. The system of claim 22, wherein the ASIC further comprises a built-in self-test component, a central processing unit, and a die-to-die communication interface.

24. The system of claim 23, wherein the custom logic comprises a double data rate physical layer (DDR PHY).
